(19) United States
(12) Patent Application Publication
(10) Pub. No.: US 2026/0254212 A1
(43) Pub. Date: Aug. 27, 2026

(54) WIRE HARNESS

(71) Applicant: SUMITOMO WIRING SYSTEMS, LTD., Yokkaichi-shi (JP)

(72) Inventors: Ryo FUJIOKA, Yokkaichi-shi (JP); Katsutoshi IZAWA, Yokkaichi-shi (JP)

(73) Assignee: SUMITOMO WIRING SYSTEMS, LTD., Yokkaichi-shi (JP)

(21) Appl. No.: 19/543,204

(22) Filed: Feb. 18, 2026

(30) Foreign Application Priority Data
Feb. 25, 2025 (JP) 2025-027531

(51) Int. Cl. H02G 3/04; B60R 16/02; H01B 7/00; H05K 9/00

(52) U.S. Cl. CPC H02G 3/0431; B60R 16/0215; H01B 7/0045; H05K 9/0098

(57) ABSTRACT

A wire harness including: a first electric wire member; and a second electric wire member of a system different from the first electric wire member, wherein: the first electric wire member includes a first electric wire, a tubular first electromagnetic shield that surrounds an outer surface of the first electric wire, and a first insulating cover that covers an outer surface of the first electromagnetic shield, and the second electric wire member includes a second electric wire, and a tubular second electromagnetic shield that surrounds an outer surface of the second electric wire.

### BACKGROUND

The present disclosure relates to a wire harness.

Conventionally, as a wire harness used in vehicles such as hybrid vehicles and electric vehicles, there is a wire harness that includes a tubular electromagnetic shielding member that collectively surrounds a plurality of electric wires (e.g., see JP 2015-076899A). The electromagnetic shielding member has an electromagnetic shielding function of suppressing the irradiation of electromagnetic waves from the electric wires to the outside of the wire harness. A braided wire, a metal foil, or the like is used as the electromagnetic shielding member.

### SUMMARY

In the above-mentioned wire harness, there is desire for the ability to suppress a decrease in electromagnetic shielding performance.

An exemplary aspect of the disclosure provides a wire harness that can suppress a decrease in electromagnetic shielding performance.

A wire harness according to an aspect of the present disclosure includes: a first electric wire member; and a second electric wire member of a system different from the first electric wire member, the first electric wire member including: a first electric wire, a tubular first electromagnetic shielding member surrounding an outer surface of the first electric wire, and a first insulating member covering an outer surface of the first electromagnetic shielding member, and the second electric wire member including: a second electric wire, and a tubular second electromagnetic shielding member surrounding an outer surface of the second electric wire, wherein the first electric wire member and the second electric wire member have a parallel routing portion in which the first electric wire member and the second electric wire member are routed in parallel, and a separate routing portion in which the first electric wire member and the second electric wire member are routed so as to extend in different directions, the first insulating member is formed on only a portion of the first electromagnetic shielding member in a length direction of the first electromagnetic shielding member, and the first insulating member covers the outer surface of the first electromagnetic shielding member in the parallel routing portion.

The wire harness according to an aspect of the present disclosure has an effect of being able to suppress a decrease in electromagnetic shielding performance.

### BRIEF DESCRIPTION OF THE DRAWINGS

FIG. 1 is a schematic configuration diagram illustrating a wire harness according to embodiments;

FIG. 2 is a schematic side view illustrating a wire harness according to a first embodiment;

FIG. 3 is a schematic cross-sectional view illustrating the wire harness according to the first embodiment;

FIG. 4 is a schematic cross-sectional view (cross-sectional view taken along line 4-4 in FIG. 2) illustrating the wire harness according to the first embodiment;

FIG. 5 is a schematic cross-sectional view (cross-sectional view taken along line 5-5 in FIG. 2) illustrating the wire harness according to the first embodiment;

FIG. 6 is a schematic cross-sectional view (cross-sectional view taken along line 6-6 in FIG. 2) illustrating the wire harness according to the first embodiment;

FIG. 7 is a schematic side view illustrating a wire harness according to a second embodiment; and

FIG. 8 is a schematic cross-sectional view (cross-sectional view taken along line 8-8 in FIG. 7) illustrating the wire harness according to the second embodiment.

### EMBODIMENTS OF THE DISCLOSURE

### Description of Embodiments of the Present Disclosure

First, embodiments of the present disclosure will be listed and described.

[1] A wire harness according to an aspect of the present disclosure includes: a first electric wire member; and a second electric wire member of a system different from the first electric wire member, the first electric wire member including: a first electric wire, a tubular first electromagnetic shielding member surrounding an outer surface of the first electric wire, and a first insulating member covering an outer surface of the first electromagnetic shielding member, and the second electric wire member including: a second electric wire, and a tubular second electromagnetic shielding member surrounding an outer surface of the second electric wire, wherein the first electric wire member and the second electric wire member have a parallel routing portion in which the first electric wire member and the second electric wire member are routed in parallel, and a separate routing portion in which the first electric wire member and the second electric wire member are routed so as to extend in different directions, the first insulating member is formed on only a portion of the first electromagnetic shielding member in a length direction of the first electromagnetic shielding member, and the first insulating member covers the outer surface of the first electromagnetic shielding member in the parallel routing portion.

According to this configuration, a parallel routing portion is provided in which the first electric wire member and the second electric wire member are routed in parallel. In this parallel routing portion, the first electromagnetic shielding member and the second electromagnetic shielding member are provided side by side. In this case, if the first electromagnetic shielding member and the second electromagnetic shielding member are provided on the outermost surfaces of the first electric wire member and the second electric wire member, respectively, there is a possibility that, in the parallel routing portion, the first electromagnetic shielding member may unintentionally come into contact with the second electromagnetic shielding member of a different system. If the first electromagnetic shielding member becomes electrically connected to the second electromagnetic shielding member of a different system, the impedance in the first electromagnetic shielding member and the second electromagnetic shielding member may increase, and the electromagnetic shielding performance of the wire harness may decrease.

In contrast to this, according to the above configuration, the outer surface of the first electromagnetic shielding member in the parallel routing portion is covered by the first insulating member. Therefore, even if the first electric wire member comes into contact with the second electric wire member in the parallel routing portion, it is possible to favorably suppress the case where the first electromagnetic shielding member comes into direct contact with the second electromagnetic shielding member. This makes it possible to favorably suppress the case where the first electromagnetic shielding member and the second electromagnetic shielding member become electrically connected to each other, thereby making it possible to favorably suppress a decrease in the electromagnetic shielding performance of the wire harness.

[2] In aspect [1] above, an aspect is possible in which the wire harness further includes a tubular member collectively housing the first electric wire member and the second electric wire member in the parallel routing portion, wherein the first insulating member covers the outer surface of a portion of the first electromagnetic shielding member that is housed in the tubular member.

According to this configuration, the first electric wire member and the second electric wire member are collectively housed inside one tubular member. Therefore, there is a possibility that the first electric wire member and the second electric wire member can come into contact with each other inside the tubular member. However, in the above configuration, the outer surface of the portion of the first electromagnetic shielding member housed in the tubular member is covered by the first insulating member. Therefore, even if the first electric wire member comes into contact with the second electric wire member inside the tubular member, it is possible to favorably suppress the case where the first electromagnetic shielding member comes into direct contact with the second electromagnetic shielding member.

[3] In aspect [2] above, an aspect is possible in which the wire harness further includes a tubular branch member connected to an end portion of the tubular member, wherein the branch member collectively houses a portion of the first electric wire member and a portion of the second electric wire member that are drawn out from the tubular member, and the branch member has a branching structure that branches the first electric wire member and the second electric wire member into different paths.

According to this configuration, the first electric wire member and the second electric wire member can be favorably branched into different paths from each other by the branch member having a branching structure.

[4] In aspect [3] above, an aspect is possible in which the wire harness further includes: a first outer casing member housing a portion of the first electric wire member that is drawn out from the branch member; and a second outer casing member housing a portion of the second electric wire member that is drawn out from the branch member, wherein the branch member includes: a first connecting tube portion connected to an end portion of the tubular member, a second connecting tube portion connected to an end portion of the first outer casing member, and a third connecting tube portion connected to an end portion of the second outer casing member, the first connecting tube portion collectively houses the first electric wire member and the second electric wire member, the second connecting tube portion houses only the first electric wire member, the third connecting tube portion houses only the second electric wire member, and the first insulating member covers the outer surface of the first electromagnetic shielding member in at least a portion of the branch member that is housed in the first connecting tube portion.

According to this configuration, the branching structure of the branch member is formed by the first connecting tube portion, the second connecting tube portion, and the third connecting tube portion. The first electric wire member and the second electric wire member are collectively housed inside the first connecting tube portion. Therefore, there is a possibility that the first electric wire member and the second electric wire member can come into contact with each other inside the first connecting tube portion. However, in the above configuration, the outer surface of the portion of the first electromagnetic shielding member housed in the first connecting tube portion is covered by the first insulating member. Therefore, even if the first electric wire member comes into contact with the second electric wire member inside the first connecting tube portion, it is possible to favorably suppress the case where the first electromagnetic shielding member comes into direct contact with the second electromagnetic shielding member.

[5] In any one of aspects [1] to [4] above, an aspect is possible in which the first insulating member is a tubular insulating tube, and the first electric wire member has a fixing member that fixes the first insulating member to the outer surface of the first electromagnetic shielding member.

According to this configuration, the insulating tube that covers the outer surface of the first electromagnetic shielding member is fixed to the outer surface of the first electromagnetic shielding member by the fixing member. This makes it possible to suppress the case where the insulating tube shifts in position relative to the first electromagnetic shielding member in the length direction of the first electromagnetic shielding member.

[6] In any one of aspects [1] to [5] above, an aspect is possible in which the second electric wire member has a second insulating member covering an outer surface of the second electromagnetic shielding member, the second insulating member is formed on only a portion of the second electromagnetic shielding member in a length direction of the second electromagnetic shielding member, and the second insulating member covers the outer surface of the second electromagnetic shielding member in the parallel routing portion.

According to the above configuration, the outer surface of the second electromagnetic shielding member in the parallel routing portion is covered by the second insulating member. Therefore, even if the first electric wire member comes into contact with the second electric wire member in the parallel routing portion, it is possible to favorably suppress the case where the first electromagnetic shielding member comes into direct contact with the second electromagnetic shielding member. This makes it possible to more favorably suppress the case where the first electromagnetic shielding member and the second electromagnetic shielding member become electrically connected to each other, thereby making it possible to more favorably suppress a decrease in the electromagnetic shielding performance of the wire harness.

[7] A wire harness according to an aspect of the present disclosure includes: a first electric wire member including a first electric wire and a tubular first electromagnetic shielding member surrounding an outer surface of the first electric wire; a second electric wire member of a system different from the first electric wire member and including a second electric wire and a tubular second electromagnetic shielding member surrounding an outer surface of the second electric wire; a tubular connecting member electrically connected to an end portion of the first electromagnetic shielding member and end portion of the second electromagnetic shielding member, the first electric wire and the second electric wire passing through the connecting member; and a third electromagnetic shielding member electrically connected to the connecting member and collectively surrounding the first electric wire and the second electric wire, wherein the first electric wire member and the second electric wire member have a parallel routing portion in which the first electric wire and the second electric wire are routed in parallel, and a separate routing portion in which the first electric wire and the second electric wire are routed so as to extend in different directions, the first electromagnetic shielding member surrounds the outer surface of the first electric wire in the separate routing portion, the second electromagnetic shielding member surrounds the outer surface of the second electric wire in the separate routing portion, and the third electromagnetic shielding member collectively surrounds the first electric wire and the second electric wire in the parallel routing portion.

According to this configuration, a parallel routing portion is provided in which the first electric wire and the second electric wire are routed in parallel. The portions of the first electric wire and the second electric wire that are in the parallel routing portion are collectively surrounded by the one third electromagnetic shielding member. In other words, the first electromagnetic shielding member and the second electromagnetic shielding member of different systems are not provided in the parallel routing portion. Therefore, in the parallel routing portion, the first electromagnetic shielding member and the second electromagnetic shielding member of different systems do not come into contact with each other. This makes it possible to favorably suppress the case where the first electromagnetic shielding member and the second electromagnetic shielding member become electrically connected to each other, and it is possible to favorably suppress a decrease in the electromagnetic shielding performance of the wire harness.

[8] In aspect [7] above, an aspect is possible in which the wire harness further includes: a tubular member surrounding an outer surface of the third electromagnetic shielding member; and a tubular branch member connected to an end portion of the tubular member, wherein the branch member houses the connecting member, and the branch member has a branching structure that branches the first electric wire member and the second electric wire member into different paths.

According to this configuration, the outer surface of the third electromagnetic shielding member provided in the parallel routing portion is surrounded by the tubular member. Also, the connecting member is housed inside the branch member connected to the end portion of the tubular member. The first electric wire member and the second electric wire member can be favorably branched into different paths from each other by the branch member having a branching structure.

### Details of Embodiments of the Present Disclosure

Specific examples of a wire harness of the present disclosure will be described below with reference to the drawings. In the drawings, some parts of configurations may be exaggerated or simplified for convenience of description. Furthermore, in the drawings, the arrangements of components are shown schematically to facilitate understanding the features, and therefore the arrangements of components may differ from one drawing to another. Furthermore, the dimensional ratios of components may differ between drawings. The term “tubular” as used in the description of this specification does not only refer to a shape having a peripheral wall that continuously extends entirely around in the circumferential direction, but also includes a tubular shape formed by combining multiple components, and a C-like shape having a cutout or the like along a portion of the circumference. Note that a “tubular” shape is a concept including, but not limited to, a circle, an ellipse, and a polygon having sharp or rounded corners. In this specification, the term “facing” refers to surfaces or members that directly face each other. In this specification, the term “facing” includes not only the case where the entirety of members face each other, but also cases where portions of members face each other. Also, in this specification, the term “facing” includes both a case where two portions have another member interposed between them, and a case where nothing is interposed between the two portions. Furthermore, terms such as “first,” “second,” and “third” are used in this specification simply to distinguish between objects and are not used to rank objects. Note that the present disclosure is not limited to these examples, but rather is defined by the scope of the claims, and is intended to include all modifications within the meaning and scope equivalent to the claims.

### First Embodiment

A first embodiment of a wire harness will be described below.

### Overall configuration of wire harness 10

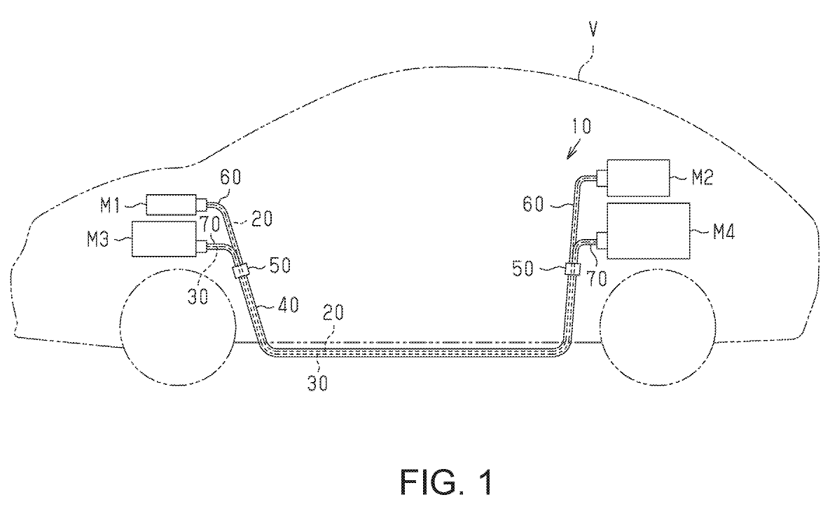

A wire harness 10 shown in FIG. 1 electrically connects two or three or more electrical devices M1, M2, M3, and M4. The wire harness 10 is mounted in, for example, a vehicle V such as a hybrid vehicle or an electric vehicle. The wire harness 10 includes a first electric wire member 20 that electrically connects the electrical device M1 and the electrical device M2 to each other, and a second electric wire member 30 that electrically connects the electrical device M3 and the electrical device M4 to each other. Here, the first electric wire member 20 and the second electric wire member 30 are electric wire members of different systems. In other words, the first electric wire member 20 and the second electric wire member 30 constitute different circuits from each other. Also, examples of the electrical devices M1, M2, M3, and M4 include an inverter, a high-voltage battery, a motor for driving wheels, and a relay box.

The wire harness 10 includes a tubular member 40 (tube) through which the first electric wire member 20 and the second electric wire member 30 pass, and tubular branch members 50 (tubular branches) provided at the two end portions of the tubular member 40. The wire harness 10 has tubular outer casing members 60 that surround the portions of the first electric wire member 20 drawn out from the branch members 50, and tubular outer casing members 70 that surround the portions of the second electric wire member 30 drawn out from the branch members 50. The tubular member 40, the branch members 50, and the outer casing members 60 and 70 (outer casings) function as protective members that protect the first electric wire member 20 and the second electric wire member 30 housed therein from flying objects and water droplets.

The first electric wire member 20 and the second electric wire member 30 have a parallel routing portion (parallel router) in which the first electric wire member 20 and the second electric wire member 30 are routed so as to extend parallel with each other, and separate routing portions (separate routers) in which the first electric wire member 20 and the second electric wire member 30 are routed so as to extend in different directions from each other. In the parallel routing portion, the first electric wire member 20 and the second electric wire member 30 are provided side by side. In the parallel routing portion, electric wire members of a plurality of systems (two systems in the present embodiment), that is, the first electric wire member 20 and the second electric wire member 30, are housed together inside the tubular member 40. In other words, the tubular member 40 collectively houses the first electric wire member 20 and the second electric wire member 30 in the parallel routing portion. Here, in this specification, “collectively house” means, for example, that the first electric wire member 20 and the second electric wire member 30 are housed together in one space, without a wall being provided between the first electric wire member 20 and the second electric wire member 30. The portions of the first electric wire member 20 and the second electric wire member 30 drawn out from the tubular member 40 are collectively housed inside the branch members 50, and are branched into different paths from each other by the branch members 50. The portions of the first electric wire member 20 and the second electric wire member 30 that are branched into different paths are housed inside the outer casing members 60 and the outer casing members 70, respectively. In other words, in the separate routing portions, the first electric wire member 20 is housed on its own inside the outer casing members 60, and the second electric wire member 30 is housed on its own inside the outer casing members 70.

### Configuration of first electric wire member 20

The first electric wire member 20 is routed from the electrical device M1 to the electrical device M2 in such a manner that, for example, a portion of the first electric wire member 20 in the length direction thereof passes under the floor of the vehicle V. One end portion of the first electric wire member 20 is connected to the electrical device M1, and the other end portion of the first electric wire member 20 is connected to the electrical device M2.

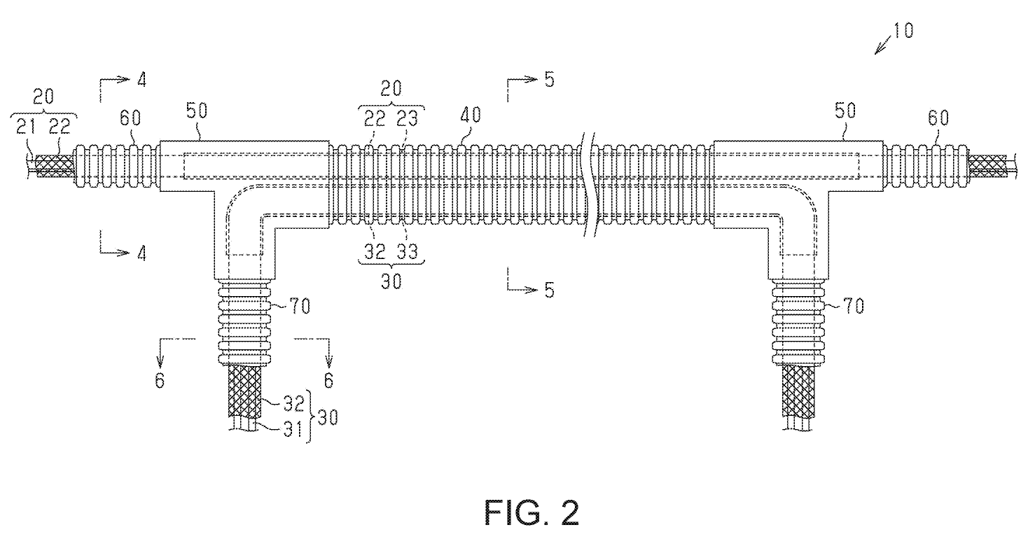

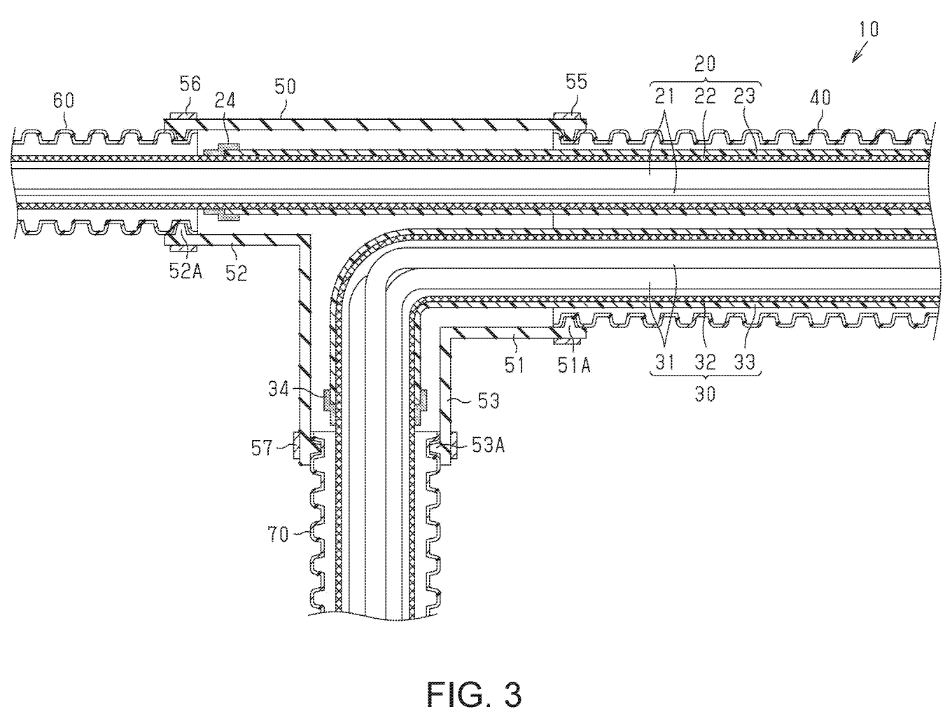

As shown in FIGS. 2 and 3, the first electric wire member 20 has one or more first electric wires 21, a tubular first braided member 22 that covers the outer surfaces of the first electric wires 21, and a first insulating member 23 (first insulating cover) that covers the outer surface of the first braided member 22. The first electric wire member 20 of the present embodiment has two first electric wires 21. Note that in FIGS. 2 and 3, the outer casing members 60 and 70, the first electric wire member 20, and the second electric wire member 30 are shown in a state of being cut at intermediate portions.

### Configuration of first electric wires 21

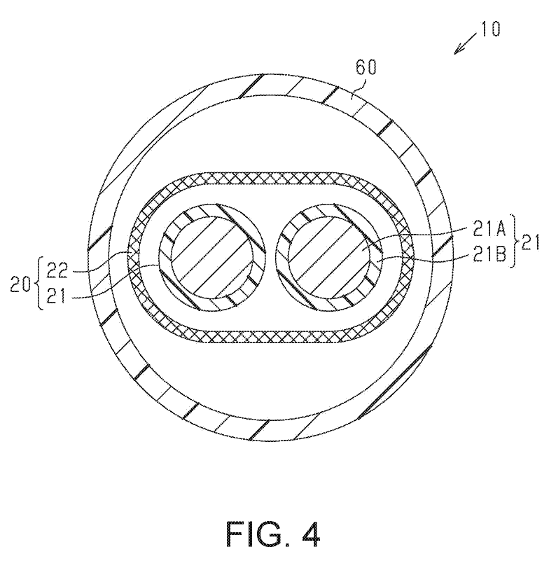

As shown in FIG. 4, each of the first electric wires 21 is a coated electric wire having a core wire 21A made of a conductor and an insulating coating 21B that coats the outer surface of the core wire 21A. Each of the first electric wires 21 is, for example, a high-voltage electric wire capable of handling a high voltage and a large current. Each of the first electric wires 21 is, for example, a non-shielded electric wire that does not itself have an electromagnetic shield structure.

The core wire 21A can be, for example, a stranded wire obtained by twisting together a plurality of metal wires, or a single core wire made of a single conductor. The core wire 21A can be made of, for example, a metal material such as a copper-based or aluminum-based metal.

The insulating coating 21B completely surrounds the core wire 21A in the circumferential direction. The insulating coating 21B is made of, for example, a resin material having insulating properties.

A cross-section of each of the first electric wires 21 cut along a plane perpendicular to the length direction of the first electric wires 21, that is, a transverse cross-section of each of the first electric wires 21, can have any shape. Each of the first electric wires 21 in the present embodiment has a circular cross-sectional shape.

### Configuration of first braided member 22

The first braided member 22 is shaped as tube that collectively surrounds the first electric wires 21. The first braided member 22 collectively surrounds the first electric wires 21. In other words, the first braided member 22 is a multi-core collective shield braided wire. The first braided member 22 is formed so as to surround the outer surfaces of first electric wires 21 over substantially the entire length of the first electric wires 21 in the length direction thereof.

The first braided member 22 can be, for example, a braided wire formed by braiding a plurality of metal wires, or a braided wire formed by braiding a combination of metal wires and resin wires. The metal wires can be made of, for example, a metal material such as a copper-based or aluminum-based metal. Note that the figures schematically show a state in which the metal wires of the first braided member 22 have been braided. Furthermore, the end portions of the first braided member 22 are directly or indirectly connected to a ground member (not shown) such as the vehicle body or a metal case. The first braided member 22 having this configuration functions as a first electromagnetic shielding member (first electromagnetic shield).

### Configuration of first insulating member 23

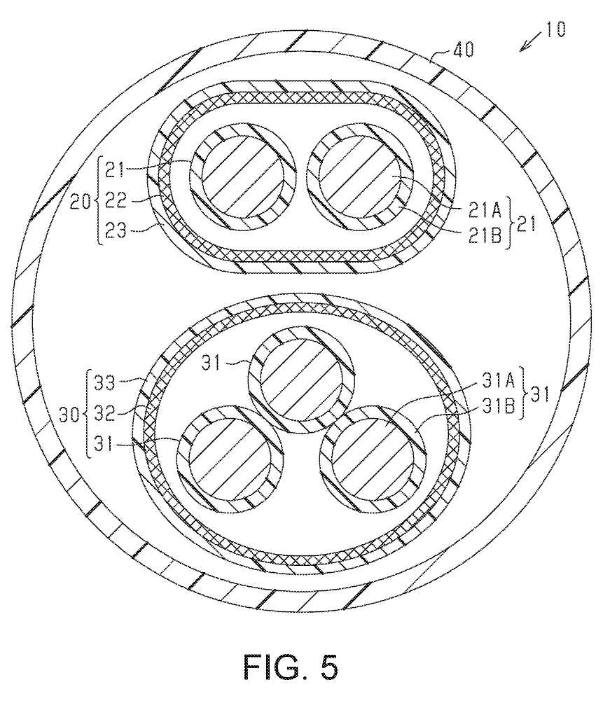

As shown in FIG. 5, the first insulating member 23 is formed so as to cover the outer surface of the first braided member 22. The first insulating member 23 is formed so as to, for example, completely surround the outer surface of the first braided member 22 in the circumferential direction. Note that the inner circumferential surface of the first insulating member 23 may be in close contact with the outer circumferential surface of the first braided member 22, or may not be in close contact with the outer circumferential surface of the first braided member 22.

As shown in FIG. 2, the first insulating member 23 is formed only on a portion of the first braided member 22 in the length direction thereof. In other words, the first insulating member 23 is not formed over the entire length of the first braided member 22 in the length direction thereof. The first insulating member 23 is formed so as to cover the outer surface of the first braided member 22 in the parallel routing portion. In other words, the first insulating member 23 is formed so as to cover the outer surface of the portion of the first braided member 22 in which the second electric wire members 30 are routed in parallel. More specifically, the first insulating member 23 is formed so as to cover the outer surface of the portion of the first braided member 22 housed in the tubular member 40. The first insulating member 23 is formed so as to cover the outer surface of the entire length of the portion of the first braided member 22 housed in the tubular member 40. The first insulating member 23 is formed so as to cover the outer surface of the portion of the first braided member 22 housed in each of the branch members 50. As shown in FIG. 3, the first insulating member 23 is formed so as to, for example, cover the outer surface of a portion, in the length direction, of the first braided member 22 inside the branch member 50. The first insulating member 23 is not formed on the outer surface of the portion of the first braided member 22 housed in the outer casing member 60. In other words, the first insulating member 23 is formed so as to expose the outer surface of the portion of the first braided member 22 housed in the outer casing member 60.

The first insulating member 23 can be, for example, an insulating tube. The insulating tube is made of, for example, a resin material having insulating properties. The insulating tube can be, for example, a heat-shrinkable tube or a non-shrinkable tube. The first insulating member 23 in the present embodiment is a non-shrinkable tube. The non-shrinkable tube can be made of, for example, a synthetic resin containing, as the main component, a polyolefin resin or a polyvinyl chloride resin. In the present embodiment, the first braided member 22, which surrounds the outer surfaces of the two first electric wires 21, is passed through the inside of a non-shrinkable tube, thereby forming the first insulating member 23 that covers the outer surface of the first braided member 22.

The first insulating member 23 of the present embodiment is fixed to the outer surface of the first braided member 22 by a fixing member 24. This makes it possible to suppress the case where the first insulating member 23 shifts in position relative to the first braided member 22 in the length direction of the first braided member 22. The fixing member 24 can be, for example, a tape member, a cable tie, or a crimp band. The fixing member 24 in the present embodiment is a tape member. The fixing member 24 is formed so as to fix an end portion in the length direction of the first insulating member 23 to the outer circumferential surface of the first braided member 22. For example, the fixing member 24 is wound around the outer circumferential surface of the end portion of the first insulating member 23 in the length direction and the portion of the outer circumferential surface of the first braided member 22 that is exposed from the first insulating member 23. For example, the fixing member 24 is continuously wound around a range extending from the outer circumferential surface of the first insulating member 23 to the outer circumferential surface of the first braided member 22. The fixing member 24 has an overlap winding structure, for example.

Here, “overlap winding structure” refers to a structure in which the tape member is spirally wound such that predetermined portions in the width direction of the tape member overlap each other. One example of an overlap winding structure is half-lap winding, in which the tape member is spirally wound such that portions corresponding to approximately half of the tape member in the width direction overlap each other.

### Configuration of second electric wire member 30

As shown in FIG. 1, the second electric wire member 30 is routed from the electrical device M3 to the electrical device M4 in such a manner that, for example, a portion of the second electric wire member 30 in the length direction thereof passes under the floor of the vehicle V. One end portion of the second electric wire member 30 is connected to the electrical device M3, and the other end portion of the second electric wire member 30 is connected to the electrical device M4.

As shown in FIGS. 2 and 3, the second electric wire member 30 has one or more second electric wires 31, a tubular second braided member 32 that covers the outer surfaces of the second electric wires 31, and a second insulating member 33 (second insulating cover) that covers the outer surface of the second braided member 32. The second electric wire member 30 of the present embodiment has three second electric wires 31.

### Configuration of second electric wire 31

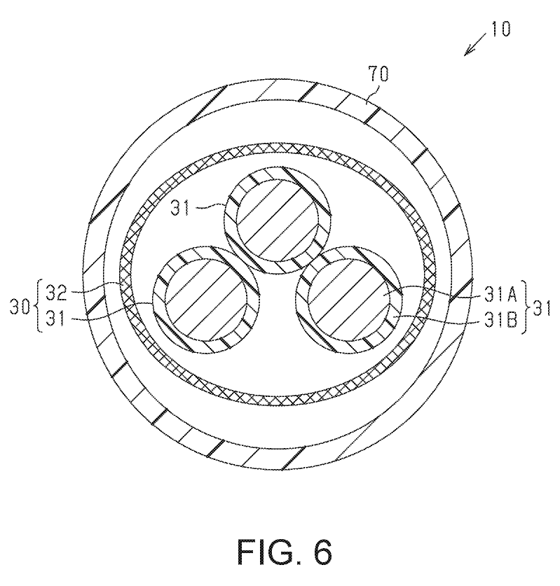

As shown in FIG. 6, each of the second electric wires 31 is a coated electric wire having a core wire 31A made of a conductor and an insulating coating 31B that coats the outer surface of the core wire 31A. Each of the second electric wires 31 is, for example, a high-voltage electric wire capable of handling a high voltage and a large current. Each of the second electric wires 31 is, for example, a non-shielded electric wire.

The core wire 31A can be, for example, a stranded wire or a single core wire. The core wire 31A can be made of, for example, a metal material such as a copper-based or aluminum-based metal.

The insulating coating 31B surrounds the entirety of the outer surface of the core wire 31A in the circumferential direction. The insulating coating 31B is made of, for example, a resin material having insulating properties.

The second electric wires 31 can have any cross-sectional shape. Each of the second electric wires 31 in the present embodiment has a circular cross-sectional shape.

### Configuration of second braided member 32

The second braided member 32 is shaped as tube that collectively surrounds the second electric wires 31. In other words, the second braided member 32 is a multi-core collective shield braided wire. The second braided member 32 is formed so as to surround the second electric wires 31 over substantially the entire length of the second electric wires 31 in the length direction thereof.

The second braided member 32 can be, for example, a braided wire formed by braiding a plurality of metal wires, or a braided wire formed by braiding a combination of metal wires and resin wires. The metal wires can be made of, for example, a metal material such as a copper-based or aluminum-based metal. Note that the figures schematically show a state in which the metal wires of the second braided member 32 have been braided. Furthermore, the end portions of the second braided member 32 are directly or indirectly connected to a ground member (not shown) such as the vehicle body or a metal case. The second braided member 32 having this configuration functions as a second electromagnetic shielding member (second electromagnetic shield).

### Configuration of second insulating member 33

As shown in FIG. 5, the second insulating member 33 is formed so as to cover the outer surface of the second braided member 32. The second insulating member 33 is formed so as to, for example, completely surround the second braided member 32 in the circumferential direction. Note that the inner circumferential surface of the second insulating member 33 may be in close contact with the outer circumferential surface of the second braided member 32, or may not be in close contact with the outer circumferential surface of the second braided member 32.

As shown in FIG. 2, the second insulating member 33 is formed only on a portion of the second braided member 32 in the length direction thereof. In other words, the second insulating member 33 is not formed over the entire length of the second braided member 32 in the length direction thereof. The second insulating member 33 is formed so as to cover the outer surface of the second braided member 32 in the parallel routing portion. In other words, the second insulating member 33 is formed so as to cover the outer surface of the portion of the second braided member 32 in which the first electric wire members 20 are routed in parallel. More specifically, the second insulating member 33 is formed so as to cover the outer surface of the portion of the second braided member 32 housed in the tubular member 40. The second insulating member 33 is formed so as to cover the outer surface of the entire length of the portion of the second braided member 32 housed in the tubular member 40. The second insulating member 33 is formed so as to cover the outer surface of the portion of the second braided member 32 housed in each of the branch members 50. As shown in FIG. 3, the second insulating member 33 is formed so as to, for example, cover the outer surface of a portion, in the length direction, of the second braided member 32 inside the branch member 50. The second insulating member 33 is not formed on the outer surface of the portion of the second braided member 32 housed in the outer casing member 70. In other words, the second insulating member 33 is formed so as to expose the outer surface of the portion of the second braided member 32 housed in the outer casing member 70.

The second insulating member 33 can be, for example, an insulating tube. The second insulating member 33 in the present embodiment is a non-shrinkable tube. In the present embodiment, the second braided member 32, which surrounds the outer surfaces of the three second electric wires 31, is passed through the inside of a non-shrinkable tube, thereby forming the second insulating member 33 that surrounds the outer surface of the second braided member 32.

The second insulating member 33 of the present embodiment is fixed to the outer surface of the second braided member 32 by a fixing member 34. This makes it possible to suppress the case where the second insulating member 33 shifts in position relative to the second braided member 32 in the length direction of the second braided member 32. The fixing member 34 can be, for example, a tape member, a cable tie, or a crimp band. The fixing member 34 in the present embodiment is a tape member. The fixing member 34 is formed so as to fix an end portion in the length direction of the second insulating member 33 to the outer circumferential surface of the second braided member 32. For example, the fixing member 34 is wound around the outer circumferential surface of the end portion of the second insulating member 33 in the length direction and the portion of the outer circumferential surface of the second braided member 32 that is exposed from the second insulating member 33. For example, the fixing member 34 is continuously wound around a range extending from the outer circumferential surface of the second insulating member 33 to the outer circumferential surface of the second braided member 32. The fixing member 34 has an overlap winding structure, for example.

### Configuration of tubular member 40

As shown in FIG. 2, the tubular member 40 is provided, for example, at an intermediate portion of the wire harness 10 in the length direction thereof. The tubular member 40 is provided between the two branch members 50. The tubular member 40 has an elongated tubular shape. The tubular member 40 of the present embodiment has a cylindrical shape. The tubular member 40 can be, for example, a pipe made of a synthetic resin, a protector made of a synthetic resin, or a corrugated tube made of a synthetic resin. The tubular member 40 of the present embodiment is a corrugated tube having a bellows structure in which the diameter repeatedly increases and decreases in the axial direction of the tubular member 40. The tubular member 40, which is a corrugated tube, has flexibility due to the bellows structure, and can be easily bent. Note that the tubular member 40 can be made of, for example, a synthetic resin such as polyolefin, polyamide, polyester, or ABS resin.

The tubular member 40 surrounds the outer surfaces of the portions of the first electric wire member 20 and the second electric wire member 30 that are provided between the two branch members 50. The tubular member 40 collectively houses the portions of the first electric wire member 20 and the second electric wire member 30 in the parallel routing portion. In other words, the single internal space of the tubular member 40 collectively houses electric wire members of a plurality of systems routed in parallel, that is, houses the first electric wire member 20 and the second electric wire member 30 together. At this time, inside the tubular member 40, the outer surface of the first braided member 22 of the first electric wire member 20 is covered by the first insulating member 23, and the outer surface of the second braided member 32 of the second electric wire member 30 is covered by the second insulating member 33. In other words, as shown in FIG. 5, the tubular member 40 completely surrounds the outer surface of the first insulating member 23 in the circumferential direction, and also completely surrounds the outer surface of the second insulating member 33 in the circumferential direction.

### Configuration of outer casing members 60 and 70

As shown in FIG. 1, the outer casing members 60 and 70 are provided at, for example, both end portions of the wire harness 10 in the length direction thereof. Each of the outer casing members 60 and 70 has an elongated tubular shape. Each of the outer casing members 60 and 70 of the present embodiment has a cylindrical shape.

As shown in FIG. 3, the outer casing members 60 house the portions of the first electric wire member 20 in the separate routing portions. Out of the first electric wire member 20 and the second electric wire member 30, the outer casing members 60 house only the first electric wire member 20. At this time, inside each of the outer casing members 60, the outer circumferential surface of the first braided member 22 of the first electric wire member 20 is exposed from the first insulating member 23. As shown in FIG. 4, the outer casing member 60 completely surrounds the outer surface of the first braided member 22 in the circumferential direction.

As shown in FIG. 3, the outer casing members 70 house the portions of the second electric wire member 30 in the separate routing portions. Out of the first electric wire member 20 and the second electric wire member 30, the outer casing members 70 house only the second electric wire member 30. At this time, inside the outer casing member 70, the outer circumferential surface of the second braided member 32 of the second electric wire member 30 is exposed from the second insulating member 33. As shown in FIG. 6, the outer casing member 70 completely surrounds the outer surface of the second braided member 32 in the circumferential direction.

The outer casing members 60 and 70 shown in FIG. 3 can each be, for example, a synthetic resin pipe, a synthetic resin protector, a synthetic resin corrugated tube, or a rubber waterproof cover. Each of the outer casing members 60 and 70 in the present embodiment is a corrugated tube.

### Configuration of branch member 50

The branch members 50 each have a tubular shape as a whole. The branch members 50 are provided between the tubular member 40 and the outer casing members 60 and 70. Each of the branch members 50 surrounds the outer surfaces of the portions of the first electric wire member 20 and the second electric wire member 30 provided between the tubular member 40 and the outer casing members 60 and 70. The branch members 50 completely surround the outer surfaces of the first electric wire member 20 and the second electric wire member 30 in the circumferential direction. The branch members 50 can be, for example, a synthetic resin pipe, a synthetic resin protector, a synthetic resin corrugated tube, or a rubber waterproof cover. The branch members 50 of the present embodiment are each a rubber waterproof cover.

The branch members 50 have a branching structure for branching the first electric wire member 20 and the second electric wire member 30 into different paths from each other. Each of the branch members 50 has, for example, a first connecting tube portion 51 connected to the outer surface of the tubular member 40, a second connecting tube portion 52 connected to the outer surface of the outer casing member 60, and a third connecting tube portion 53 connected to the outer surface of the outer casing member 70. The second connecting tube portion 52 is formed so as to extend from the first connecting tube portion 51 toward the left side in the figure. The third connecting tube portion 53 is formed so as to extend in a direction (here, downward in the figure) different from the direction in which the second connecting tube portion 52 extends from the first connecting tube portion 51. A branching structure is formed by the first connecting tube portion 51, the second connecting tube portion 52, and the third connecting tube portion 53. Each of the branch members 50 is a single component in which the first connecting tube portion 51, the second connecting tube portion 52, and the third connecting tube portion 53 are integrally formed and continuous with each other.

The first connecting tube portion 51 is fitted around the outer surface of the tubular member 40. The first connecting tube portion 51 of the present embodiment has a cylindrical shape. One or more lips 51A (here, one lip) that engage with the tubular member 40, which is a corrugated tube, for example, is formed on the inner circumferential surface of the first connecting tube portion 51. The lip 51A is formed so as to fit into an annular recess of the tubular member 40 when the first connecting tube portion 51 is fitted around the outer surface of the tubular member 40, for example.

The first connecting tube portion 51 collectively houses the first electric wire member 20 and the second electric wire member 30 in the parallel routing portion. In other words, the single internal space of the first connecting tube portion 51 collectively houses electric wire members of a plurality of systems routed in parallel, that is, houses the first electric wire member 20 and the second electric wire member 30 together. At this time, inside the first connecting tube portion 51, the outer surface of the first braided member 22 is covered by the first insulating member 23, and the outer surface of the second braided member 32 is covered by the second insulating member 33. In other words, the first connecting tube portion 51 completely surrounds the outer surface of the first insulating member 23 in the circumferential direction, and also completely surrounds the outer surface of the second insulating member 33 in the circumferential direction.

A coupling member 55, for example, is provided on the outer circumferential surface of the first connecting tube portion 51. The coupling member 55 can be, for example, a resin or metal cable tie, a crimping ring, or a tape member. The first connecting tube portion 51 is fixed to the outer surface of the tubular member 40 by being constricted from the outer circumferential side by the coupling member 55. The first connecting tube portion 51 is constricted from the outer circumferential side by the coupling member 55 until the first connecting tube portion 51 comes into liquid-tight contact with the tubular member 40.

The second connecting tube portion 52 is fitted around the outer surface of the outer casing member 60. The second connecting tube portion 52 of the present embodiment has a cylindrical shape. One or more (here, one) lips 52A that engage with the outer casing member 60, which is a corrugated tube, for example, is formed on the inner circumferential surface of the second connecting tube portion 52. The lip 52A is formed so as to fit into an annular recess of the outer casing member 60 when the second connecting tube portion 52 is fitted around the outer surface of the outer casing member 60, for example.

The second connecting tube portion 52 houses the first electric wire member 20 in the separate routing portion. Out of the first electric wire member 20 and the second electric wire member 30, the second connecting tube portion 52 houses only the first electric wire member 20. Note that inside the second connecting tube portion 52, the outer surface of one portion of the first braided member 22 in the length direction is covered by the first insulating member 23, and the outer surface of the remaining portion of the first braided member 22 is exposed from the first insulating member 23.

A coupling member 56, for example, is provided on the outer circumferential surface of the second connecting tube portion 52. The coupling member 56 can be, for example, a resin or metal cable tie, a crimping ring, or a tape member. The second connecting tube portion 52 is fixed to the outer surface of the outer casing member 60 by being constricted from the outer circumferential side by the coupling member 56. The second connecting tube portion 52 is constricted from the outer circumferential side by the coupling member 56 until the second connecting tube portion 52 comes into liquid-tight contact with the outer casing member 60.

The third connecting tube portion 53 is fitted around the outer surface of the outer casing member 70. The third connecting tube portion 53 of the present embodiment has a cylindrical shape. One or more lips 53A (here, one lip) that engage with the outer casing member 70, which is a corrugated tube, for example, is formed on the inner circumferential surface of the third connecting tube portion 53. The lip 53A is formed so as to fit into an annular recess of the outer casing member 70 when the third connecting tube portion 53 is fitted around the outer surface of the outer casing member 70, for example.

The third connecting tube portion 53 houses the second electric wire member 30 in the separate routing portion. Out of the first electric wire member 20 and the second electric wire member 30, the third connecting tube portion 53 houses only the second electric wire member 30. Note that inside the third connecting tube portion 53, the outer surface of one portion of the second braided member 32 in the length direction is covered by the second insulating member 33, and the outer surface of the remaining portion of the second braided member 32 is exposed from the second insulating member 33.

A coupling member 57, for example, is provided on the outer circumferential surface of the third connecting tube portion 53. The coupling member 57 can be, for example, a resin or metal cable tie, a crimping ring, or a tape member. The third connecting tube portion 53 is fixed to the outer surface of the outer casing member 70 by being constricted from the outer circumferential side by the coupling member 57. The third connecting tube portion 53 is constricted from the outer circumferential side by the coupling member 57 until the third connecting tube portion 53 comes into liquid-tight contact with the outer casing member 70.

### Operations and effects of first embodiment

Next, effects of the first embodiment will be described.

(1-1) The wire harness 10 is provided with the parallel routing portion in which the first electric wire member 20 and the second electric wire member 30 are routed in parallel. In this parallel routing portion, the first braided member 22 and the second braided member 32 are provided side by side. In this case, if the first braided member 22 and the second braided member 32 are provided on the outermost surfaces of the first electric wire member 20 and the second electric wire member 30, respectively, there is a possibility that, in the parallel routing portion, the first braided member 22 may unintentionally come into contact with the second braided member 32 of a different system. If the first braided member 22 becomes electrically connected to the second braided member 32 of a different system due to such contact, the impedance in the first braided member 22 and the second braided member 32 may increase, and the electromagnetic shielding performance of the wire harness 10 may decrease.

In contrast to this, in the wire harness 10 of the present embodiment, the outer surface of the portion of the first braided member 22 in the parallel routing portion is covered by the first insulating member 23. Therefore, even if the first electric wire member 20 comes into contact with the second electric wire member 30 in the parallel routing portion, it is possible to favorably suppress the case where the first braided member 22 comes into direct contact with the second braided member 32. This makes it possible to favorably suppress the case where the first braided member 22 and the second braided member 32 become electrically connected to each other, thereby making it possible to favorably suppress a decrease in the electromagnetic shielding performance of the wire harness 10.

(1-2) The first insulating member 23 is formed on only a portion of the first braided member 22 in the length direction thereof. Therefore, the material cost of the first insulating member 23 can be made lower than in the case where the first insulating member 23 is formed over the entire length of the first braided member 22 in the length direction.

(1-3) The first electric wire member 20 and the second electric wire member 30 are collectively housed inside the one tubular member 40. Therefore, inside the tubular member 40, the first electric wire member 20 and the second electric wire member 30 can possibly come into contact with each other. However, in the wire harness 10 of the present embodiment, the outer surface of the portion of the first braided member 22 housed in the tubular member 40 is covered by the first insulating member 23. Therefore, even if the first electric wire member 20 comes into contact with the second electric wire member 30 inside the tubular member 40, it is possible to favorably suppress the case where the first braided member 22 comes into direct contact with the second braided member 32.

(1-4) In each of the branch members 50, a branching structure is formed by the first connecting tube portion 51, the second connecting tube portion 52, and the third connecting tube portion 53. Inside the first connecting tube portion 51, the first electric wire member 20 and the second electric wire member 30 are collectively housed. Therefore, inside the first connecting tube portion 51, the first electric wire member 20 and the second electric wire member 30 can possibly come into contact with each other. However, in the wire harness 10 of the present embodiment, the outer surface of the portion of the first braided member 22 housed in the first connecting tube portion 51 is covered by the first insulating member 23. Therefore, even if the first electric wire member 20 comes into contact with the second electric wire member 30 inside the first connecting tube portion 51, it is possible to favorably suppress the case where the first braided member 22 comes into direct contact with the second braided member 32.

(1-5) The first insulating member 23, which is an insulating tube that covers the outer surface of the first braided member 22, is fixed to the outer surface of the first braided member 22 by the fixing member 24. Therefore, it is possible to suppress the case where the first insulating member 23 shifts in position relative to the first braided member 22 in the length direction of the first braided member 22.

(1-6) The outer surface of the portion of the second braided member 32 in the parallel routing portion is covered by the second insulating member 33. Therefore, even if the first electric wire member 20 comes into contact with the second electric wire member 30 in the parallel routing portion, it is possible to favorably suppress the case where the first braided member 22 and the second braided member 32 come into direct contact with each other. This makes it possible to more favorably suppress the case where the first braided member 22 and the second braided member 32 become electrically connected to each other, therefore making it possible to more favorably suppress the case where the electromagnetic shielding performance of the wire harness 10 decreases.

### Second Embodiment

A second embodiment of the wire harness will be described below. The following description focuses on differences from the first embodiment. Note that components the same as or corresponding to those in the first embodiment are denoted by the same reference numerals, and the description of such components may be omitted in part or in whole.

### Overall configuration of wire harness 10A

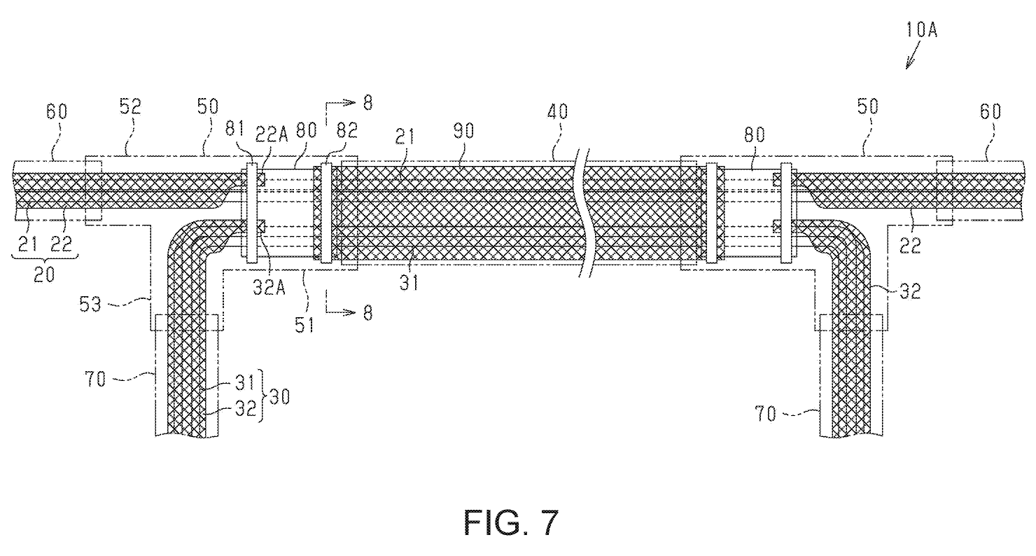

The wire harness 10A shown in FIG. 7 includes the first electric wire member 20 having the first electric wires 21, and the second electric wire member 30 having the second electric wires 31. The wire harness 10A includes the tubular member 40, the tubular branch members 50, the tubular outer casing members 60 and 70, tubular connecting members 80 (tubular connectors), and a tubular braided member 90.

The first electric wire member 20 and the second electric wire member 30 have a parallel routing portion in which the first electric wires 21 and the second electric wires 31 are routed so as to extend parallel with each other, and separate routing portions in which the first electric wires 21 and the second electric wires 31 are routed so as to extend in different directions from each other. In the parallel routing portion, the first electric wires 21 are provided side by side with the second electric wires 31. In the parallel routing portion, electric wires of a plurality of systems (two systems in the present embodiment), that is, the first electric wires 21 and the second electric wires 31, are housed together inside the tubular member 40.

### Configuration of first electric wire member 20

The first electric wire member 20 of the present embodiment has a plurality of first braided members 22. The plurality of first braided members 22 are provided on only portions of the first electric wires 21 in the length direction thereof. The first braided members 22 are formed so as to surround the outer surfaces of the first electric wires 21 in the separate routing portion. The first braided members 22 surround the outer surfaces of the portions of the first electric wires 21 drawn out from the connecting members 80.

### Configuration of second electric wire member 30

The second electric wire member 30 of the present embodiment has a plurality of second braided members 32. The plurality of second braided members 32 are provided on only portions of the second electric wires 31 in the length direction thereof. The second braided members 32 are formed so as to surround the outer surfaces of the second electric wires 31 in the separate routing portion. The second braided members 32 surround the outer surfaces of the portions of the second electric wires 31 drawn out from the connecting members 80.

### Configuration of connecting member 80

The connecting members 80 are each made of metal. The connecting members 80 are housed inside the branch members 50, for example.

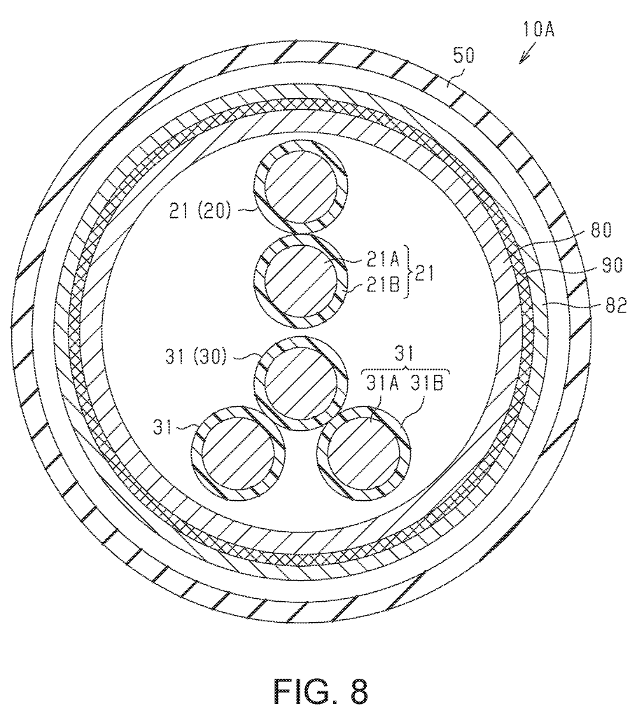

As shown in FIG. 8, each of the connecting members 80 has a tubular shape as a whole. The connecting member 80 of the present embodiment has a cylindrical shape. A plurality of the (here, two) first electric wires 21 of the first electric wire member 20 and a plurality of the (here, three) second electric wires 31 of the second electric wire member 30 pass completely through the connecting member 80. As shown in FIG. 7, the first braided member 22 and the second braided member 32 do not pass completely through the connecting member 80. In other words, the portions of the first electric wires 21 exposed from the first braided member 22 and the portions of the second electric wires 31 exposed from the second braided member 32 pass completely through the connecting member 80. In other words, the connecting member 80 collectively houses the portions of the first electric wires 21 exposed from the first braided member 22 and the portions of the second electric wires 31 exposed from the second braided member 32.

One end portion of the first braided member 22 and one end portion of the second braided member 32 are connected to the outer circumferential surface of the connecting member 80.

More specifically, a first connecting portion 22A that is connected to the outer circumferential surface of the connecting member 80 is formed so as to extend from an end portion of the first braided member 22 in the length direction thereof. The first connecting portion 22A is formed so as to bundle the metal wires that make up the first braided member 22 in a portion, in the circumferential direction, of the first braided member 22. Note that in the region in the circumferential direction of the first electric wire member 20 where the first connecting portion 22A does not exist, the first electric wires 21 are exposed from the first braided member 22. Also, a second connecting portion 32A that is connected to the outer circumferential surface of the connecting member 80 is formed so as to extend from an end portion of the second braided member 32 in the length direction thereof. The second connecting portion 32A is formed so as to bundle the metal wires that make up the second braided member 32 in a portion, in the circumferential direction, of the second braided member 32. Note that in the region in the circumferential direction of the second electric wire member 30 where the second connecting portion 32A is not present, the second electric wires 31 are exposed from the second braided member 32.

The first connecting portion 22A and the second connecting portion 32A are connected to the outer circumferential surface of the connecting member 80 by a coupling member 81. The coupling member 81 can be, for example, a resin or metal cable tie or a crimping ring. The coupling member 81 is fitted to the outer surface of the connecting member 80 in such a manner that the first connecting portion 22A and the second connecting portion 32A are sandwiched between the coupling member 81 and the outer circumferential surface of the connecting member 80. The first connecting portion 22A and the second connecting portion 32A are firmly fixed to the outer circumferential surface of the connecting member 80 by being constricted from the outer circumferential side by the coupling member 81. As a result, the first connecting portion 22A and the second connecting portion 32A are mechanically and electrically connected to the outer circumferential surface of the connecting member 80.

The first connecting portion 22A and the second connecting portion 32A are provided at positions spaced apart from each other in the circumferential direction of the connecting member 80 when they are coupled to the connecting member 80, for example. The first connecting portion 22A and the second connecting portion 32A are each connected to only a portion, in the circumferential direction, of the outer circumferential surface of the connecting member 80. In other words, the first connecting portion 22A and the second connecting portion 32A are each partially connected to the outer circumferential surface of the connecting member 80 in the circumferential direction.

The connecting member 80 is electrically connected to a ground member (not shown) through the first braided member 22 and the second braided member 32. The connecting member 80 having this configuration also functions as an electromagnetic shielding member (electromagnetic shield).

### Configuration of braided member 90

The braided member 90 is formed so as to collectively surround the outer surfaces of the first electric wires 21 and the second electric wires 31 in the parallel routing portion. The braided member 90 is provided between the two connecting members 80. The braided member 90 is provided so as to span from the end portion of one of the connecting members 80 to the end portion of the other connecting member 80. The braided member 90 collectively surrounds the outer surfaces of the portions of the first electric wires 21 and the second electric wires 31 provided between the two connecting members 80. In this case, the portions of the first electric wires 21 provided between the two connecting members 80 are not surrounded by the first braided member 22. Furthermore, the portions of the second electric wires 31 provided between the two connecting members 80 are not surrounded by the second braided member 32. As shown in FIG. 8, the braided member 90 collectively surrounds the outer surfaces of the portions of the first electric wires 21 that are not surrounded by the first braided member 22 and the outer surfaces of the portions of the second electric wires 31 that are not surrounded by the second braided member 32. In other words, the electric wires of different systems routed in parallel, that is, the first electric wires 21 and the second electric wires 31, are collectively surrounded by the one braided member 90. In this way, the braided member 90 is a multi-core collective shield braided wire that collectively surrounds the outer surfaces of the first electric wires 21 and the second electric wires 31 of different systems.

The braided member 90 can be, for example, a braided wire formed by braiding a plurality of metal wires, or a braided wire formed by braiding a combination of metal wires and resin wires. The metal wires can be made of, for example, a metal material such as a copper-based or aluminum-based metal. Note that the figures schematically show a state in which the metal wires of the braided member 90 have been braided.

As shown in FIG. 7, the end portions of the braided member 90 in the axial direction thereof are connected to the outer circumferential surfaces of the corresponding connecting members 80. Each of the end portions of the braided member 90 in the axial direction is coupled to the outer circumferential surface of the corresponding connecting member 80 by a coupling member 82. The coupling member 82 can be, for example, a resin or metal cable tie or a crimping ring. The coupling member 82 is fitted around the connecting member 80 in such a manner that the end portion of the braided member 90 is sandwiched between the coupling member 82 and the outer circumferential surface of the connecting member 80. The end portion of the braided member 90 is firmly fixed to the outer circumferential surface of the connecting member 80 by being constricted from the outer circumferential side by the coupling member 82. As a result, the braided member 90 is mechanically and electrically connected to the outer circumferential surface of the connecting member 80. Furthermore, the braided member 90 is electrically connected to a ground member (not shown) through the connecting member 80, the first braided member 22, and the second braided member 32. The braided member 90 having this configuration functions as a third electromagnetic shielding member (third electromagnetic shield).

As shown in FIG. 8, when the end portion of the braided member 90 in the axial direction coupled to the connecting member 80, the end portion completely surrounds the outer surface of the connecting member 80 in the circumferential direction. At this time, the coupling member 82 completely surrounds the outer surface of the braided member 90 in the circumferential direction.

As shown in FIG. 7, the tubular member 40 surrounds the outer surface of the braided member 90. The branch members 50 are connected to the end portions of the tubular member 40 and also to the end portions of the outer casing members 60 and 70. The first connecting tube portions 51 of the branch members 50 house the connecting members 80, for example. The second connecting tube portions 52 of the branch members 50 surround the outer surface of the first braided members 22. The third connecting tube portions 53 of the branch members 50 surround the outer surface of the second braided members 32.

### Operations and effects of second embodiment

Next, effects of the second embodiment will be described.

(2-1) The wire harness 10A is provided with the parallel routing portion in which the first electric wires 21 and the second electric wires 31 are routed in parallel. The portions of the first electric wires 21 and the second electric wires 31 in this parallel routing portion are collectively surrounded by the one braided member 90. In other words, the first braided member 22 and the second braided member 32 of different systems are not provided in the parallel routing portion. Therefore, in the parallel routing portion, the first braided member 22 and the second braided member 32 of different systems do not come into contact with each other. This makes it possible to favorably suppress the case where the first braided member 22 and the second braided member 32 become electrically connected to each other, thereby making it possible to suppress a decrease in the electromagnetic shielding performance of the wire harness 10A.

### Modified Examples

The above-described embodiments can be modified as follows, for example. The above-described embodiments and the following modified examples can be implemented in combination with each other as long as no technical contradiction arises.

The range over which the first insulating member 23 is formed in the first embodiment can be changed as appropriate. There is no particular limitation on the range over which the first insulating member 23 is formed as long as it is formed so as to cover the outer surface of at least the portion of the first braided member 22 in the parallel routing portion.

In the case where a portion of the first braided member 22 in the parallel routing portion is housed in the first connecting tube portion 51, the first insulating member 23 may be formed so as to cover the outer surface of the first braided member 22 in at least the portion of the branch member 50 that is housed in the first connecting tube portion 51. In this case, inside the second connecting tube portion 52, the first insulating member 23 may be formed so as to cover the outer surface of the first braided member 22 over the entire length thereof, or may be formed so as to expose the outer surface of the first braided member 22 over the entire length thereof.

The range over which the second insulating member 33 is formed in the first embodiment can be changed as appropriate. There is no particular limitation on the range over which the second insulating member 33 is formed as long as it is formed so as to cover the outer surface of at least the portion of the second braided member 32 in the parallel routing portion.

In the case where a portion of the second braided member 32 in the parallel routing portion is housed in the first connecting tube portion 51, the second insulating member 33 may be formed so as to cover the outer surface of the second braided member 32 in at least the portion of the branch member 50 that is housed in the first connecting tube portion 51. In this case, inside the second connecting tube portion 52, the second insulating member 33 may be formed so as to cover the outer surface of second braided member 32 over the entire length thereof, or may be formed so as to expose the outer surface of the second braided member 32 over the entire length thereof.

In the first embodiment, the first insulating member 23 and the second insulating member 33 are each illustrated as being constituted by an insulating tube, but the present disclosure is not limited to this. For example, the first insulating member 23 may be constituted by a tape member or an insulating coating. In the case where a tape member is used as the first insulating member 23, the first insulating member 23 can be formed by winding the tape member in an overlapping manner or a rough manner around the outer surface of the first braided member 22. Furthermore, in the case where an insulating coating is used as the first insulating member 23, the first insulating member 23 can be formed by applying a coating to the surface of the first braided member 22. For example, the first insulating member 23 may be formed by immersing the first braided member 22 in a solution of the material serving as the first insulating member 23, or the first insulating member 23 may be formed by applying the material serving as the first insulating member 23 by spray coating. Note that similarly to the first insulating member 23, the second insulating member 33 may be constituted by a tape member or an insulating coating.

The fixing members 24 and 34 in the first embodiment may be omitted.

In the first embodiment, either the first insulating member 23 or the second insulating member 33 may be omitted. For example, in the case where the second insulating member 33 is omitted, out of the first braided member 22 and the second braided member 32, only the outer surface of the first braided member 22 is covered by the first insulating member 23. Here, when electric wire members of N (N is a natural number of 2 or more) different systems are routed in parallel, it is sufficient to provide insulating members for the electric wire members of at least N-1 systems.

In the second embodiment, the connecting member 80 is housed inside the branch member 50, but the present disclosure is not limited to this. For example, the connecting member 80 may be housed inside the tubular member 40.

The braided member 90 in the second embodiment may be replaced with another electromagnetic shielding member such as a metal foil.

The configuration of the first electric wire member 20 in the above embodiments can be modified as appropriate.

The first braided member 22 in the above embodiments may be replaced with another electromagnetic shielding member such as a metal foil.

In the above embodiments, the number of first electric wires 21 included in the first electric wire member 20 is not particularly limited, and the number of first electric wires 21 can be changed depending on the specifications of the vehicle V. For example, the number of first electric wires 21 included in the first electric wire member 20 may be one, or may be three or more.

The configuration of the second electric wire member 30 in the above embodiments can be modified as appropriate.

The second braided member 32 in the above embodiments may be replaced with another electromagnetic shielding member such as a metal foil.

In the above embodiments, the number of second electric wires 31 included in the second electric wire member 30 is not particularly limited, and the number of second electric wires 31 can be changed depending on the specifications of the vehicle V. For example, the number of second electric wires 31 included in the second electric wire member 30 may be one, may be two, or may be four or more.

In the above embodiments, the number of electric wire members included in the wire harnesses 10 and 10A is not particularly limited, and the number of electric wire members can be changed depending on the specifications of the vehicle V. For example, the wire harnesses 10 and 10A may have electric wire members of three or more systems.

In the above embodiments, the outer casing members 60 and 70 may be omitted.

In the above embodiments, the branch member 50 may be omitted.

The relative positions of the electrical devices M1, M2, M3, and M4 in the vehicle V are not limited to those illustrated in the above embodiments, and may be changed as appropriate depending on the configuration of the vehicle V.

The embodiments disclosed herein should be considered to be illustrative in all respects and not restrictive. The scope of the present disclosure is defined by the claims, not by the meaning described above, and is intended to include all modifications within the meaning and scope of the claims.

What is claimed is:

1. A wire harness comprising:
a first electric wire member; and
a second electric wire member of a system different from the first electric wire member, wherein:
the first electric wire member includes:
a first electric wire,
a tubular first electromagnetic shield that surrounds an outer surface of the first electric wire, and
a first insulating cover that covers an outer surface of the first electromagnetic shield,
the second electric wire member includes:
a second electric wire, and
a tubular second electromagnetic shield that surrounds an outer surface of the second electric wire,
the first electric wire member and the second electric wire member have a parallel router in which the first electric wire member and the second electric wire member are routed in parallel, and a separate router in which the first electric wire member and the second electric wire member are routed so as to extend in different directions,
the first insulating cover is formed on only a portion of the first electromagnetic shield in a length direction of the first electromagnetic shield, and
the first insulating cover covers the outer surface of the first electromagnetic shield in the parallel router.

2. The wire harness according to claim 1, further comprising:
a tube that collectively houses the first electric wire member and the second electric wire member in the parallel router,
wherein the first insulating cover covers the outer surface of a portion of the first electromagnetic shield that is housed in the tube.

3. The wire harness according to claim 2, further comprising:
a tubular branch that is connected to an end of the tube, wherein:
wherein the tubular branch collectively houses a portion of the first electric wire member and a portion of the second electric wire member that are drawn out from the tube, and
the tubular branch has a branching structure that branches the first electric wire member and the second electric wire member into different paths.

4. The wire harness according to claim 3, further comprising:
a first outer casing that houses a portion of the first electric wire member that is drawn out from the tubular branch; and
a second outer casing that houses a portion of the second electric wire member that is drawn out from the tubular branch, wherein:
the tubular branch includes:
a first connecting tube portion connected to an end of the tube,
a second connecting tube portion connected to an end of the first outer casing, and
a third connecting tube portion connected to an end of the second outer casing,
the first connecting tube portion collectively houses the first electric wire member and the second electric wire member,
the second connecting tube portion houses only the first electric wire member,
the third connecting tube portion houses only the second electric wire member, and
the first insulating cover covers the outer surface of the first electromagnetic shield in at least a portion of the tubular branch that is housed in the first connecting tube portion.

5. The wire harness according to claim 1, wherein:
the first insulating cover is a tubular insulating tube, and
the first electric wire member has a fixing member that fixes the first insulating cover to the outer surface of the first electromagnetic shield.

6. The wire harness according to claim 1, wherein:
the second electric wire member has a second insulating cover that covers an outer surface of the second electromagnetic shield,
the second insulating cover is formed on only a portion of the second electromagnetic shield in a length direction of the second electromagnetic shield, and
the second insulating cover covers the outer surface of the second electromagnetic shield in the parallel router.

7. A wire harness comprising:
a first electric wire member that includes a first electric wire and a tubular first electromagnetic shield that surrounds an outer surface of the first electric wire;
a second electric wire member of a system different from the first electric wire member that includes a second electric wire and a tubular second electromagnetic shield that surrounds an outer surface of the second electric wire;
a tubular connector that is electrically connected to an end of the first electromagnetic shield and an end of the second electromagnetic shield, the first electric wire and the second electric wire passing through the tubular connector; and
a third electromagnetic shield that is electrically connected to the tubular connector and collectively surrounding the first electric wire and the second electric wire, wherein:
the first electric wire member and the second electric wire member have a parallel router in which the first electric wire and the second electric wire are routed in parallel, and a separate router in which the first electric wire and the second electric wire are routed so as to extend in different directions,
the first electromagnetic shield surrounds the outer surface of the first electric wire in the separate router,
the second electromagnetic shield surrounds the outer surface of the second electric wire in the separate router, and
the third electromagnetic shield collectively surrounds the first electric wire and the second electric wire in the parallel router.

8. The wire harness according to claim 7, further comprising:
a tube that surrounds an outer surface of the third electromagnetic shield; and
a tubular branch that is connected to an end of the tube, wherein:
the tubular branch houses the tubular connector, and
the tubular branch has a branching structure that branches the first electric wire member and the second electric wire member into different paths.
